(19) United States
(12) Patent Application Publication
(10) Pub. No.: US 2025/0179360 A1
(43) Pub. Date: Jun. 5, 2025

(54) SILICON NITRIDE ETCHING LIQUID COMPOSITION

(71) Applicant: KANTO KAGAKU KABUSHlKI KAISHA, TOKYO (JP)

(72) Inventors: Takuo Owada, TOKYO (JP); Yuki Yoshida, TOKYO (JP); Kohei Mochida, TOKYO (JP); Fukito Kuramoto, TOKYO (JP)

(73) Assignee: KANTO KAGAKU KABUSHlKI KAISHA, TOKYO (JP)

(21) Appl. No.: 18/842,598

(22) PCT Filed: May 11, 2023
(86) PCT No.: PCT/JP2023/017726

§ 371 Date: Aug. 29, 2024

(30) Foreign Application Priority Data
May 16, 2022 (JP) 2022-079909

(51) Int. Cl. C09K 13/06; H01L 21/311

(52) U.S. Cl. CPC C09K 13/06; H01L 21/31111

(57) ABSTRACT

Disclosed is a silicon nitride etching liquid composition for manufacturing 3D nonvolatile memory cells, etc., which comprises phosphoric acid, a hydrolysate of a water-soluble silicon compound, and water.

### FIELD OF THE INVENTION

The present invention relates to a silicon nitride etching liquid composition for manufacturing 3D non-volatile memory cells and the like, and a method for manufacturing 3D non-volatile memory cells and the like using the etching liquid composition.

### BACKGROUND OF THE INVENTION

In recent years, technological innovation of NAND flash memories has being progressing in the field of non-volatile memories, which are memories that retain data without applied power. NAND flash memories are used as storage devices such as smart media and SSDs.

The structure of NAND flash memory was conventionally flat (FIG. 1). With the progress of miniaturization, the line width became narrower to thus adversely affect its lifespan and performance. Recently, the development of 3D type (FIG. 2) has being progressed, and vertical-stacking technique makes it possible to manufacture a wide line width. Accordingly, longer lifespan, higher speed, and larger capacity than conventional types can be achieved.

One example of a method for manufacturing a 3D NAND flash memory comprises the steps of: (1) in a substrate with alternately stacked layers of silicon oxide and silicon nitride, (2) forming holes by dry etching, (3) embedding a gate electrode (p-Si electrode) covered with an insulating film (silicon oxide) in the hole, (4) forming a groove (space) by dry etching, (5) performing ion implantation on the substrate surface to form an impurity region, (6) etching the silicon nitride by wet etching, (7) depositing a film of TiN as a barrier metal and a film of W as an electrode on the exposed substrate and silicon oxide surfaces, and (8) etching the TIN and W collectively by a mixed acid.

As an etching solution composition for etching silicon nitride in the above step (6) (FIG. 3), an etching solution composition comprising phosphoric acid, ammonium ions, and a silicon compound has been disclosed (Patent documents 1 to 3).

When phosphoric acid and a silicon compound are comprised in the etching solution composition, they react to generate Si(OH)x. When Si(OH)x is present, the etching rates of silicon oxide and silicon nitride are both decreased. But since the decrease in the etching rate of silicon oxide is large, the etching selectivity ratio of silicon nitride to silicon oxide is improved. On the other hand, when Si(OH)x is excessively present, the saturation solubility is exceeded and Si(OH)x adheres to the silicon oxide surface, causing the regrowth of silicon oxide (hereinafter referred to as “regrowth of silicon oxide”) (FIG. 4). Patent documents 1 to 3 describe that ammonium ions in the etching solution composition combine with Si(OH)x to form a water-soluble compound, thereby suppressing the regrowth of silicon oxide.

Furthermore, as silicon nitride etching liquid compositions, an etching solution composition comprising inorganic acid, siloxane compounds, ammonium-based compounds, and a solvent (Patent document 4), an etching solution composition comprising phosphoric acid, a composite silane consisting of two or more silane compounds, and water (Patent document 5), and an etching solution composition comprising phosphoric acid, an organic compound containing silicon, and an organic solvent (Patent Document 6) are also disclosed.

### PRIOR ART DOCUMENTS

Patent document 1: U.S. Pat. No. 8,940,182
Patent document 2: U.S. Pat. No. 9,136,120
Patent document 3: U.S. Pat. No. 9,368,647
Patent document 4: JP2018-085513
Patent document 5: JP2018-182312
Patent document 6: JP2000-058500
Patent document 7: JP2020-145343

### SUMMARY OF THE INVENTION

As the number of layers in 3D NAND memory cells increases, the inventors conducted extensive research to improve the etching selectivity ratio of silicon nitride to silicon oxide, and found an etching solution composition which comprises phosphoric acid, one or more silane coupling agents and water, but does not comprise ammonium ions (Patent document 7). However, general silane coupling agents contain alkoxy groups, which generate alcohol, a volatile organic compound (VOC), upon hydrolysis. In this case, acids such as phosphoric acid may act as catalysts, and a violent hydrolysis reaction may occur. In addition, silane coupling agents containing alkoxy groups take a long time to dissolve in aqueous phosphoric acid solution, leading to increased manufacturing costs. Furthermore, as the number of layers in 3D NAND increases, the amount of Si(OH)ₓ generated during the dissolution of silicon nitride increases, and the amount of silane coupling agent required to suppress regrowth of silicon oxide also increases. As a result, a higher amount of alcohol is generated when phosphoric acid is added, and depending on the composition. The resulted solution may be classified as a hazardous material under the Fire Service Act, making it difficult to use with conventional etching equipment. Therefore, the inventors have carried out studies aimed at providing a silicon nitride etching liquid composition that can, in the manufacture of 3D nonvolatile memory cells and the like, selectively etch silicon nitride with a practical etching selectivity ratio relative to silicon oxide, suppress regrowth of silicon oxide, and prevent the generation of leaving alcohol during mixing.

In the course of intensive research to solve the above problems, the inventors found that, in the manufacture of 3D nonvolatile memory cells and the like, a silicon nitride etching composition comprising phosphoric acid and a hydrolysate of water-soluble silicon compounds can selectively etch silicon nitride with a practical etching selectivity ratio relative to silicon oxide, suppress the regrowth of silicon oxide, improve the solubility of the hydrolysate of silicon compounds in phosphoric acid, and further suppress the generation of leaving alcohol when the silicon compound is added by the use of the hydrolysate. As a result of further research, the present invention has been completed.

The inventors of the present invention estimate the reason, as follows, regarding why a silicon nitride etching composition, which comprising phosphoric acid, a hydrolysate of water-soluble silicon compounds and water, can, in the manufacture of 3D nonvolatile memory cells and the like, selectively etch silicon nitride with a practical etching selectivity ratio relative to silicon oxide, suppress regrowth of silicon oxide, improve the solubility of the hydrolysate of the silicon compound in phosphoric acid, and suppress the generation of leaving alcohol during the hydrolysis reaction.

That is to say, by comprising phosphoric acid and a hydrolysate of water-soluble silicon compounds in the etching solution composition, these components react and are adsorbed onto the silicon oxide surface, resulting in an improvement of etching selectivity ratio of silicon nitride to silicon oxide. In addition, it is estimated that by comprising a hydrolysate of water-soluble silicon compounds in the etching solution composition, the adhesion of Si(OH)ₓ to the silicon oxide surface is prevented, and the regrowth of silicon oxide can be suppressed (FIG. 5). In addition, it is estimated that the use of a hydrolysate of water-soluble silicon compounds significantly improves the solubility in phosphoric acid and further suppresses the generation of leaving alcohol.

That is, the present invention relates to the following.

(1) A silicon nitride etching liquid composition, comprising: phosphoric acid, one or more hydrolyzates of water-soluble silica compounds and water.

(2) The silicon nitride etching liquid composition as described in (1), wherein the hydrolyzate of water-soluble silica compound is a hydrolyzate of silane coupling agent.

(3) The silicon nitride etching liquid composition as described in (1) to (2), wherein the hydrolyzate of water-soluble silica compound is a hydrolysis condensate of silane coupling agent containing a three-dimensional structure.

(4) The silicon nitride etching liquid composition as described in (1) to (3), wherein the hydrolyzate of water-soluble silica compound is an aminoalkoxysilane hydrolysis condensate and/or a mercaptoalkoxysilane hydrolysis condensate.

(5) The silicon nitride etching liquid composition as described in (1) to (4), wherein the hydrolyzate of water-soluble silica compound is a 3-aminopropyltrialkoxysilane hydrolysis condensate.

(6) The silicon nitride etching liquid composition as described in (1) to (5), further comprising at least one selected from sulfuric acid or salts thereof, and aliphatic sulfonic acids or salts thereof.

(7) The silicon nitride etching liquid composition as described in (1) to (6), further comprising at least one selected from inorganic silicates, tetramethoxysilane, tetraethoxysilane, a hydrolysate of tetramethoxysilane, and a hydrolysate of tetraethoxysilane.

(8) The silicon nitride etching liquid composition as described in (7), wherein the inorganic silicate includes at least one selected from sodium silicate, potassium silicate, and tetramethylammonium silicate.

(9) A silicon nitride etching method with high etching selectivity to silicon oxide, characterized by the use of a composition comprising phosphoric acid, one or more hydrolyzates of water-soluble silica compounds and water.

The etching solution composition of the present invention can, in the manufacture of 3D nonvolatile memory cells, selectively etch silicon nitride with a practical etching selectivity ratio to silicon oxide, suppress regrowth of silicon oxide, and prevent the generation of leaving alcohol during hydrolysis. In other words, silicon nitride can be selectively etched safely, quickly, and economically without the need to separately dissolve silicon nitride in the etching solution composition. Furthermore, since the etching solution composition can suppress the regrowth of silicon oxide even without comprising ammonium ions, the manufacturing cost of the etching solution composition can be reduced.

In addition, when the etching solution composition of the present invention further comprises sulfuric acid or salts thereof, aliphatic sulfonic acid or salts thereof, inorganic silicates, tetramethoxysilane, tetraethoxysilane, a hydrolysate of tetramethoxysilane, or a hydrolysate of tetraethoxysilane, the etching selectivity ratio of silicon nitride to silicon oxide can be further improved.

### BRIEF DESCRIPTION OF THE DRAWINGS

FIG. 1 is a drawing showing the structure of a planar NAND flash memory.

FIG. 2 is a drawing showing the structure of a 3D NAND flash memory.

FIG. 3 is a drawing showing the state before and after etching of silicon nitride.

FIG. 4 is a drawing showing the principle of silicon oxide regrowth.

FIG. 5 is a drawing showing the principle of silicon oxide regrowth inhibition.

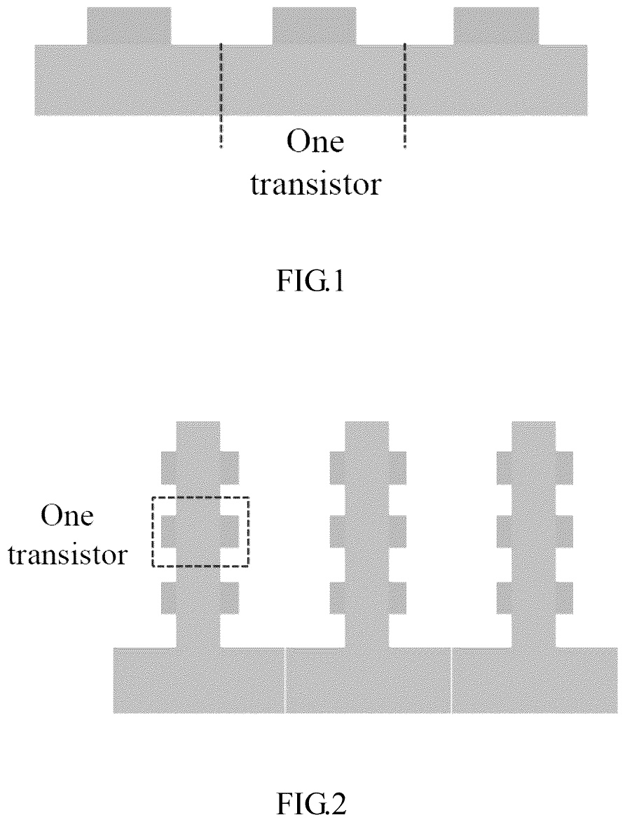

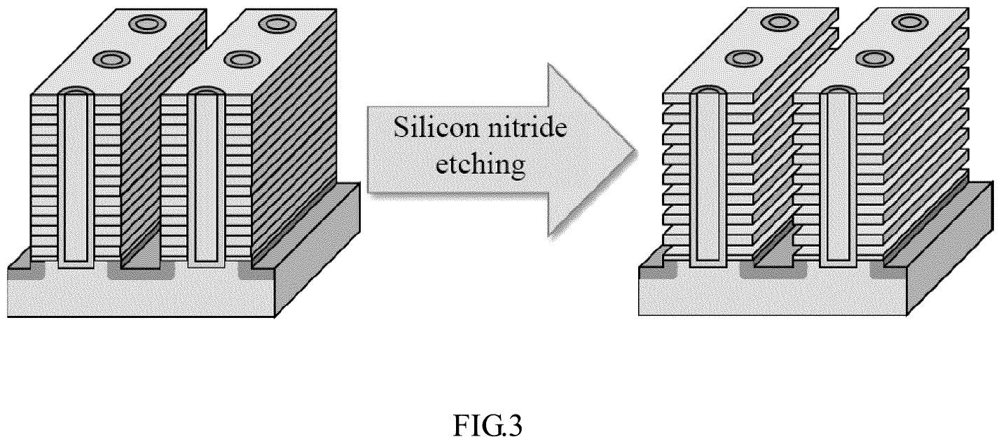

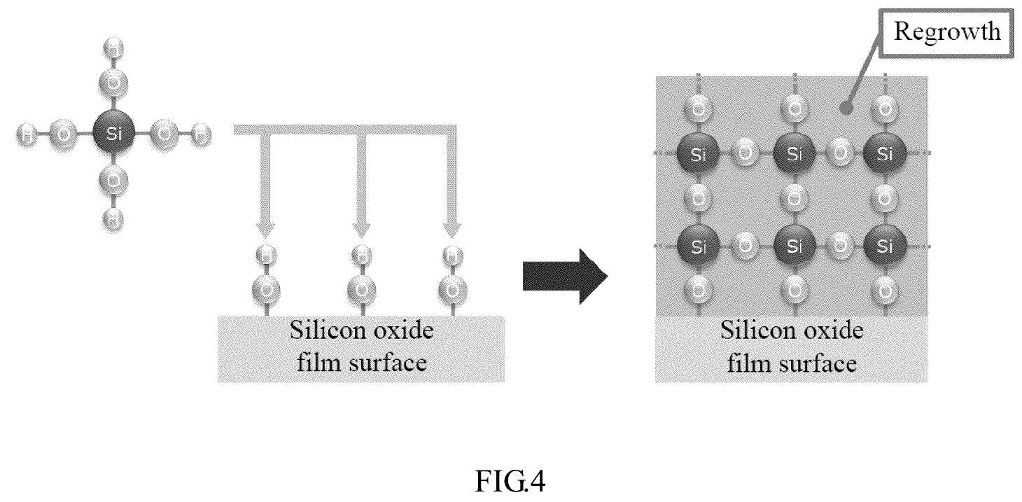

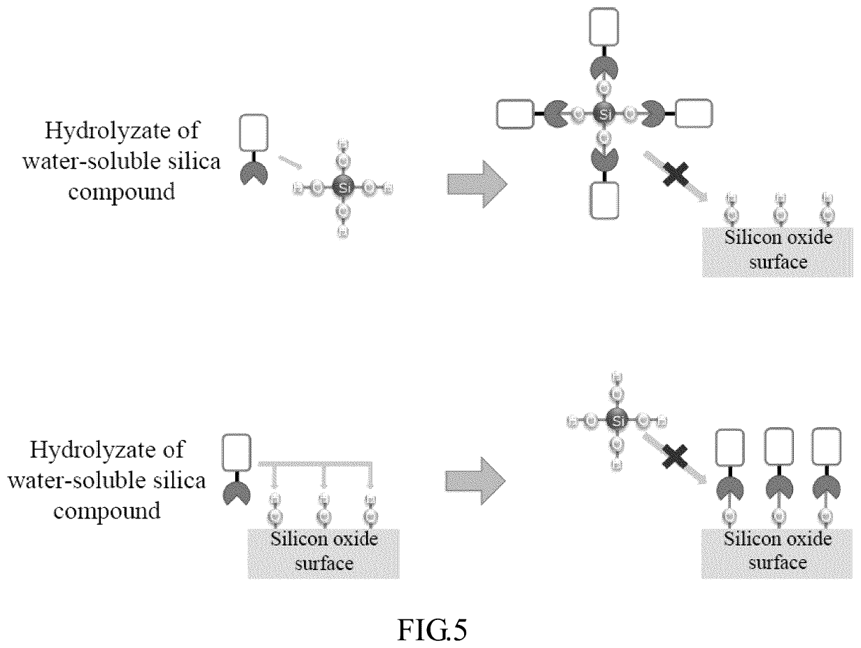

### DETAILED DESCRIPTION OF THE PREFERRED EXAMPLES

The present invention will be described in detail below based on preferred embodiments of the present invention.

The present invention is relates to a silicon nitride etching liquid composition, comprising: phosphoric acid, one or more hydrolyzates of water-soluble silica compounds and water, has high etching selectivity to silicon oxide, and inhibits regrowth of silicon oxide.

The etching solution composition of the present invention is a silicon nitride etching liquid composition for producing 3D nonvolatile memory cells and the like.

The 3D nonvolatile memory is not particularly limited in type or operation format as long as it is a 3D type nonvolatile memory, and examples thereof include 3D NAND flash memory, etc. The etching solution composition of the present invention is particularly suitable for manufacturing 3D nonvolatile memories especially having high stacking or a high aspect ratio of a unit cell, and examples thereof include those having a silicon oxide film with a thickness of 10 nm to 50 nm.

The hydrolysate of water-soluble silicon compound used in the present invention is not particularly limited, but is preferred as the compound represented by formula (1):

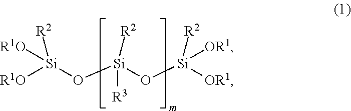

wherein R¹ is either an H atom or an alkyl group, which may be the same or different from each other; R² is an alkyl group of C1 to C10 comprising at least one selected from the group consisting of an H atom, an N atom, an S atom, a Cl atom, and an F atom, which may be the same or different from each other and; and R³ is represented by formula (2):

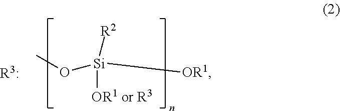

wherein R³, R¹O or OR¹, and Si may form a ring by condensation, and m and n are integers from 1 to 1000. The compound represented by formula 1 is preferably a hydrolysate of aminoalkoxysilane or a hydrolysate of mercaptoalkoxysilane, more preferably a hydrolysate of 3-aminopropyltrialkoxysilane, and even more preferably a compound in which R¹ is any one of an H atom, a methyl group, and an ethyl group, and R² is a 3-aminopropyl group. Furthermore, m and n are integers from 1 to 1000, preferably from 1 to 500, and more preferably from 1 to 100.

The hydrolysate of water-soluble silicon compounds may be used alone or in combination. The concentration of the hydrolysate of water-soluble silicon compounds in the etching solution composition is not particularly limited, but is preferably 0.01 to 30% by weight, more preferably 0.5 to 30% by weight, and even more preferably 0.5 to 25% by weight.

The etching solution composition of the present invention comprises phosphoric acid. The concentration of phosphoric acid in the etching solution composition is not particularly limited, but is preferably 40 to 95% by weight, and more preferably 50 to 95% by weight.

The etching solution composition of the present invention comprises the above-mentioned hydrolysate of water-soluble silicon compounds and phosphoric acid, which react with each other and are adsorbed onto the silicon oxide surface, thereby selectively etching silicon nitride relative to silicon oxide. Furthermore, the adhesion of Si(OH)ₓ to the silicon oxide surface is prevented, the regrowth of silicon oxide is suppressed, and the generation of leaving alcohol during the hydrolysis reaction is prevented.

In the etching solution composition of the present invention, water constitutes the balance except for phosphoric acid, a hydrolysate of water-soluble silicon compounds, and additional components which may be comprised as described below.

The etching solution composition of the present invention may further comprise sulfuric acid or salts thereof, or aliphatic sulfonic acid or a salt thereof, thereby improving the etching selectivity of silicon nitride relative to silicon oxide.

The etching solution composition of the present invention may further comprises inorganic silicates, tetramethoxysilane, tetraethoxysilane, a hydrolysate of tetramethoxysilane, or a hydrolysate of tetraethoxysilane, which is preferable because it improves the selectivity ratio of silicon oxide film to silicon nitride film. Inorganic silicates, tetramethoxysilane, tetraethoxysilane, a hydrolysate of tetramethoxysilane, and a hydrolysate of tetraethoxysilane form Si(OH)ₓ in the etching solution composition.

The inorganic silicates are not particularly limited, but sodium silicate, potassium silicate, and tetramethylammonium silicate are preferred.

The etching solution composition of the present invention may further comprise additional components other than sulfuric acid or salts thereof, aliphatic sulfonic acid or salts thereof, inorganic silicates, tetramethoxysilane, tetraethoxysilane, a hydrolysate of tetramethoxysilane, and a hydrolysate of tetraethoxysilane as long as the additional components do not interfere with etching of silicon nitride, and examples of such additional components comprise fluorine compounds. The etching solution composition of the present invention preferably further comprises a fluorine compound, since the etching rate of silicon nitride is increased. As the fluorine compound, hydrofluoric acid, ammonium fluoride, and hexafluorosilicic acid are preferred, and hexafluorosilicic acid is more preferred.

The etching solution composition of the present invention may not comprise ammonium ions. The etching solution composition of the present invention can suppress regrowth of silicon oxide even without ammonium ions.

The present invention also relates to a method for manufacturing a 3D nonvolatile memory cell or the like, comprising etching silicon nitride with an etching solution composition according to the present invention. Furthermore, the present invention also relates to a 3D nonvolatile memory cell or the like obtained by the method.

Next, the etching solution composition of the present invention will be described in more detail with reference to the following examples and comparative examples, but the present invention is not limited to these.

### <Evaluation 1: Etching Selectivity Ratio of Silicon Nitride Film/Silicon Oxide Film>

### (Preparation of Wafer (Before Immersion))

A substrate with silicon nitride film formed on a Si substrate was used, and cut into a size of 20 mm×15 mm to obtain a silicon nitride wafer (before immersion). Similarly, a substrate with silicon oxide film formed was used to obtain a silicon oxide wafer (before immersion).

### (Pretreatment of Silicon Nitride Wafer)

The silicon nitride wafer (before immersion) was immersed in a 0.6 wt % aqueous solution of hydrofluoric acid and left to stand at 25° C. for 90 seconds. The wafer was then removed and rinsed with deionized water (DIW) for 1 minute to obtain a silicon nitride wafer (after pretreatment).

### (Immersion of Wafer in Etching Solution Composition)

The silicon nitride wafer (after pretreatment) was immersed in 100 mL of the etching solution composition having the composition shown in Table 1, and stirred and immersed at 160° C. for 5 to 10 minutes. The wafer was then removed and rinsed with deionized water (DIW) for 1 minute to obtain a silicon nitride wafer (after immersion). The hydrolyzate of the water-soluble silicon compound in table 1 is a hydrolysis condensate of 3-aminopropyltriethoxysilane with a three-dimensional structure, and is more specifically assumed to be a hydrolysate of 3-aminopropyltriethoxysilane represented by formula (3):

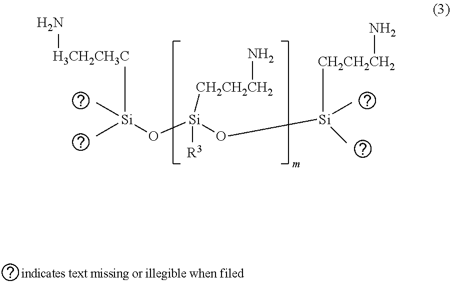

wherein R³ is represented by formula (4),

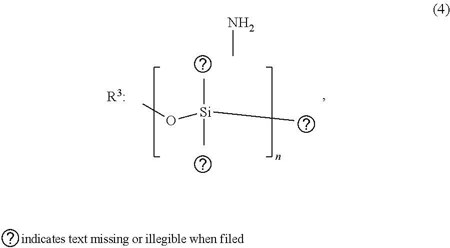

wherein R³, HO or OH, and Si may form a ring by dehydration condensation, and m and n are integers from 1 to 100.

Furthermore, the silicon oxide wafer (before immersion) was immersed in 100 mL of the etching solution composition having the composition listed in table 1, and stirred and immersed at 160° C. for 10 to 20 minutes. The wafer was then removed and rinsed with deionized water (DIW) for 1 minute to obtain a silicon oxide wafer (after immersion).

TABLE 1

| | Composition | | | | | |
|---|---|---|---|---|---|---|
| | | Hydrolyzate | | | | |
| | | of | | | | |
| | | water-soluble | | | | |
| | Phosphoric | silica | Potassium | | | |
| | acid | compound | silicate | Other ingredients | | Water |
| | (wt %) | (wt %) | (wt %) | ingredient | (wt %) | (wt %) |
| Comparative | 85.50 | — | — | — | — | 14.50 |
| example 1 | | | | | | |
| Comparative | 82.62 | — | 0.24 | — | — | 17.14 |
| example 2 | | | | | | |
| Example 1 | 65.93 | 17.17 | 0.24 | — | — | 16.66 |
| Example 2 | 54.46 | 17.54 | — | Sulfuric acid | 15.80 | 12.20 |
| Example 3 | 52.62 | 16.94 | 0.24 | Methanesulfonic | 15.27 | 14.93 |
| | | | | acid | | |
| Example 4 | 56.32 | 18.05 | — | Methanesulfonic | 13.62 | 12.01 |
| | | | | acid | | |
| Example 5 | 54.41 | 17.45 | 0.24 | Ammonium | 13.16 | 14.74 |
| | | | | sulfate | | |
| Example 6 | 53.06 | 17.73 | — | Ammonium | 7.53 | 21.68 |
| | | | | sulfate | | |
| Example 7 | 50.93 | 17.03 | 0.28 | Ammonium | 7.23 | 24.53 |
| | | | | sulfate | | |

### (Measurement of Etching Rate of Etching Solution Composition)

The thickness of the silicon nitride (after pretreatment) or silicon oxide wafer (before immersion) described above was measured using a spectroscopic ellipsometer (manufactured by J. A. Woollam, model number: RC2®), and the thickness of the silicon nitride or silicon oxide wafer (after immersion) described above was measured using a spectroscopic ellipsometer (manufactured by J. A. Woollam, model number: RC2®). From the difference in film thickness before and after immersion, the etching rate of the etching solution composition for silicon nitride or silicon oxide was calculated, and by dividing the etching rate of silicon nitride by the etching rate of silicon oxide, the etching selectivity ratio of silicon nitride film/silicon oxide film is calculated. The results are shown in table 2.

### <Evaluation 2: Presence or Absence of Silicon Oxide Regrowth> (Preparation of Wafer (Before Immersion))

A substrate having alternately laminated films of silicon nitride and silicon oxide with grooves (spaces) formed in the laminated films by dry etching was used, and cut into a size of 20 mm×15 mm to obtain a wafer for evaluation.

### (Pretreatment of Wafer for Evaluation)

The wafer for evaluation (before immersion) described above was immersed in a 0.6 wt % aqueous solution of hydrofluoric acid and left to stand at 25° C. for 90 seconds. The wafer was then taken out and rinsed with deionized water (DIW) for 1 minute to obtain a wafer for evaluation (after pretreatment).

### (Immersion of Wafer in Etching Solution Composition)

The wafer for evaluation (after pretreatment) described above was immersed in 100 mL of an etching solution composition having the composition shown in table 1, and stirred and immersed at 160° C. for 240 minutes. The wafer was then taken out and rinsed with deionized water (DIW) for 1 minute to obtain a wafer for evaluation (after immersion).

### (Confirmation of Regrowth of Silicon Oxide in Etching Solution Composition)

The wafer for evaluation (after immersion) was observed using an FE-SEM (manufactured by Hitachi High-Technologies Corporation, model number: SU8220) to confirm the presence or absence of regrowth of silicon oxide. The results are shown in table 2.

TABLE 2

| | Results | | | |
|---|---|---|---|---|
| | Etching rate (Å/min) | | Silicon nitride/silicon | Regrowth of |
| | Silicon | Silicon | oxide etching | silicon |
| | nitride | oxide | selectivity ratio | oxide |
| Comparative | 229 | 1.2 | 191 | Absence |
| example 1 | | | | |
| Comparative | 224 | 0.1↓ | 1000↑ | Presence |
| example 2 | | | | |
| Example 1 | 149 | 0.1↓ | 1000↑ | Absence |
| Example 2 | 116 | 0.1↓ | 1000↑ | Absence |
| Example 3 | 100 | 0.1↓ | 1000↑ | Absence |
| Example 4 | 109 | 0.1↓ | 1000↑ | Absence |
| Example 5 | 107 | 0.1↓ | 1000↑ | Absence |
| Example 6 | 100 | 0.1↓ | 1000↑ | Absence |
| Example 7 | 90 | 0.1↓ | 900↑ | Absence |

1. A silicon nitride etching liquid composition, comprising: phosphoric acid, one or more hydrolyzates of water-soluble silica compounds and water.

2. The silicon nitride etching liquid composition as claimed in claim 1, wherein the hydrolyzate of water-soluble silica compound is a hydrolyzate of silane coupling agent.

3. The silicon nitride etching liquid composition as claimed in claim 1, wherein the hydrolyzate of water-soluble silica compound is a hydrolysis condensate of silane coupling agent containing a three-dimensional structure.

4. The silicon nitride etching liquid composition as claimed in claim 1, wherein the hydrolyzate of water-soluble silica compound is an aminoalkoxysilane hydrolysis condensate and/or a mercaptoalkoxysilane hydrolysis condensate.

5. The silicon nitride etching liquid composition as claimed in claim 1, wherein the hydrolyzate of water-soluble silica compound is a 3-aminopropyltrialkoxysilane hydrolysis condensate.

6. The silicon nitride etching liquid composition as claimed in claim 1, further comprising at least one selected from sulfuric acid or salts thereof, and aliphatic sulfonic acids or salts thereof.

7. The silicon nitride etching liquid composition as claimed in claim 1, further comprising at least one selected from inorganic silicates, tetramethoxysilane, tetraethoxysilane, a hydrolysate of tetramethoxysilane, and a hydrolysate of tetraethoxysilane.

8. The silicon nitride etching liquid composition as claimed in claim 7, wherein the inorganic silicate includes at least one selected from sodium silicate, potassium silicate, and tetramethylammonium silicate.

9. A silicon nitride etching method with high etching selectivity to silicon oxide, characterized by the use of a composition comprising phosphoric acid, one or more hydrolyzates of water-soluble silica compounds and water.
